(19) United States
(12) Patent Application Publication
(10) Pub. No.: US 2023/0164935 A1
(43) Pub. Date: May 25, 2023

(54) LED Display Device

(71) Applicant: SHENZHEN LEYARD OPTO-ELECTRONIC CO., LTD., Shenzhen (CN)

(72) Inventors: Liyong WANG, Shenzhen (CN); Xuexiang HUANG, Shenzhen, (CN); Jinlong ZHENG, Shenzhen (CN)

(21) Appl. No.: 17/988,788

(22) Filed: Nov. 17, 2022

(30) Foreign Application Priority Data
Nov. 19, 2021 (CN) 202111400095.2
Nov. 19, 2021 (CN) 2021114000952

(51) Int. Cl. H05K 5/02; H05K 5/00

(52) U.S. Cl. CPC H05K 5/0217; H05K 5/0021

(57) ABSTRACT

Provided is a light-emitting diode (LED) display device. The LED display device includes: a support; a plurality of display assemblies mounted on a front side of the support, wherein the plurality of display assemblies are arranged in an array on the support, each display assembly is slidably arranged in an upper-lower direction, and each display assembly includes a frame and an LED display screen detachably arranged on a front side of the frame; and a plurality of gas bags, wherein each gas bag is arranged between the frames of two display assemblies adjacent to each other in the upper-lower direction, each gas bag has an expanded state and a flat state, when the gas bag is in the flat state, two adjacent display assemblies located above and below the gas bag cooperate with each other in a contact manner, and when the gas bag is switched from the flat state to the expanded state, the frame above the gas bag can be driven to slide upwards, such that a detachment gap is formed between the two adjacent display assemblies located above and below the gas bag.

### CROSS-REFERENCE TO RELATED APPLICATION

This application claims the priority to Chinese patent application No. 202111400095.2, filed to the China National Intellectual Property Administration on Nov. 19, 2021, the disclosure of which is hereby incorporated by reference in its entirety.

### TECHNICAL FIELD

The disclosure relates to a technical field of light-emitting diode (LED) display, in particular to an LED display device.

### BACKGROUND

Light-emitting diode (LED) display devices are electronic display screens composed of LED dot matrices. The forms of display contents on the screen, for example, texts, animations, pictures and videos are timely switched by turning on and off red and green lamp beads, and the display control of assemblies is implemented by means of modular structures. The LED display device includes an LED display screen, a control system and a power source system. The LED display screens are composed of LED dot matrices to emit light. The control system switches the display contents on the screens by adjusting and controlling the on/off state of areas. The power source system is used to convert input voltages and currents to satisfy the requirements of the display screen. The LED display screen can switch different forms of various information presentation modes, and can be used indoors and outdoors, with incomparable advantages over other display screens. Featuring high brightness intensity, low power consumption, low voltage requirement, small size, convenient use, long service life, stable impact resistance, and strong resistance to external interference, the LED display screen develops rapidly and has been widely applied in various fields.

The LED display devices in the related art are all formed by splicing LED display screens. Since stress deformation will be resulted from the gravity and long-term use, the gravity of the upper-layer LED display screens acts on the lower-layer LED display screens to press the lower-layer LED display screens. In this case, when the lower-layer LED display screens are required to be repaired and replaced, it will be difficult to take out the lower-layer LED display screens under pressure from the gravity.

In the prior art, when the LED display screens are in the front-maintained mode, if a certain lower-layer LED display screen is required to be repaired and replaced, all the upper-layer LED display screens above the LED display screen are required to be detached, resulting in difficult repair.

### SUMMARY

The main objective of the disclosure is to provide a light-emitting diode (LED) display device, so as to solve the problem that in the prior art, when a certain LED display screen at a lower layer is required to be repaired and replaced, all upper-layer LED display screens above the LED display screen are required to be detached, resulting in difficult repair.

In order to realize the above objective, the disclosure provides an LED display device. The LED display device includes: a support; a plurality of display assemblies mounted on a front side of the support, wherein the plurality of display assemblies are arranged in an array on the support, each display assembly is slidably arranged in an upper-lower direction, and each display assembly includes a frame and an LED display screen detachably arranged on a front side of the frame; and a plurality of gas bags, wherein each gas bag is arranged between the frames of two display assemblies adjacent to each other in the upper-lower direction, each gas bag has an expanded state and a flat state, when the gas bag is in the flat state, two adjacent display assemblies located above and below the gas bag cooperate with each other in a contact manner, and when the gas bag is switched from the flat state to the expanded state, the frame above the gas bag may be driven to slide upwards, such that a detachment gap is formed between the two adjacent display assemblies located above and below the gas bag.

In some embodiments, each gas bag includes a flat gas bag body and a gas nozzle arranged on the gas bag body, first accommodation recesses for accommodating the gas bag body are provided on the frames of the two adjacent display assemblies located above and below, and the gas nozzle passes through the frames.

In some embodiments, the LED display device further includes a gas source device for supplying gas to the plurality of gas bags, the gas source device includes a gas pump and/or an inflator, the gas source device further includes a plurality of first gas channels in communication with the gas pump and/or the inflator, the plurality of first gas channels are connected in parallel, the plurality of first gas channels are in communication with the plurality of gas bags in a one-to-one correspondence manner, and a first gate valve is arranged on each of the first gas channels.

In some embodiments, the gas source device further includes an overflow gas channel in communication with any one of the first gas channels, and an overflow valve is arranged on the overflow gas channel.

In some embodiments, the gas source device includes the gas pump and the inflator, the gas pump and the inflator are connected in parallel, the plurality of first gas channels converge at a junction, the junction is in communication with the gas pump by a second gas channel, a first one-way valve is arranged on the second gas channel, a third gas channel is arranged between an inlet of the first one-way valve and the inflator, a second one-way valve is arranged on the third gas channel, a fourth gas channel is arranged between the junction and an outlet of the first one-way valve, and a second gate valve is arranged on the fourth gas channel.

In some embodiments, the LED display device further includes a plurality of longitudinal rods arranged at intervals and a plurality of horizontal rods arranged at intervals, the longitudinal rods and the horizontal rods are arranged in a staggered manner, every two adjacent longitudinal rods pass through one frame, every two adjacent horizontal rods pass through one frame, and a movement gap in the upper-lower direction is formed between a through hole of each frame allowing the horizontal rods to pass through and a corresponding horizontal rods.

In some embodiments, a chute is provided on one frame of two adjacent frames located left and right, and a slide block matching the chute in an inserted manner is arranged on the other frame.

In some embodiments, a second accommodation recess for accommodating a ball is provided on a back side of each frame, and a portion of the ball protruding out of an opening of the second accommodation recess cooperates with a surface of the support in a contact manner.

In some embodiments, a pair of limiting members located on an upper side and a lower side of the ball is arranged on the frame, and the limiting members are detachably located in the second accommodation recess.

In some embodiments, the LED display device further includes a plurality of fasteners penetrating through the support, one corresponding frame is adjustably mounted on the support by each fastener, an avoiding hole allowing the fasteners to pass through are provided on the support, an aperture of the avoiding hole is greater than an outer diameter of each fastener, connecting holes tightly connected to the fasteners are provided on the frames, the LED display device further includes a plurality of damping members, the plurality of damping members and the plurality of fasteners are arranged in a one-to-one correspondence manner, and the damping members are located between the avoiding holes and heads of the fasteners, such that the fasteners may swing up and down in the avoiding holes when the frames slide up and down.

In some embodiments, the fasteners include screw heads and screw rods connected with the screw heads, the connecting holes are screw holes connected with the screw rods, the avoiding holes include elongated hole sections for avoiding the screw rods, and reamed hole sections for accommodating the screw heads, each reamed hole section has an aperture greater than a maximum value of apertures of the elongated hole sections, step surfaces are formed between the reamed hole sections and the elongated hole sections, the damping members include springs sleeving the screw rods, and the springs are located between the screw heads and the step surfaces.

By employing the technical solution of the disclosure, the LED display device includes: a support, a plurality of display assemblies and a plurality of gas bags. The plurality of display assemblies are mounted on a front side of the support. The plurality of display assemblies are arranged in an array on the support. Each display assembly is slidably arranged in an upper-lower direction. Each display assembly includes a frame and an LED display screen detachably arranged on a front side of the frame. Each gas bag is arranged between the frames of two display assemblies adjacent to each other in the upper-lower direction, and each gas bag has an expanded state and a flat state. In the disclosure, when the gas bag is in the flat state, two adjacent display assemblies located above and below the gas bag cooperate with each other in a contact manner. When a lower LED display screen is required to be replaced, the gas bag above the LED display screen required to be repaired is switched from the flat state to the expanded state, and the frame above the gas bag may be driven to slide upwards, such that a detachment gap is formed between the two adjacent display assemblies located above and below the gas bag. In this way, the LED display screen above the lower LED display screen required to be repaired is slightly lifted, such that the LED display screen required to be maintained is not pressed by the upper LED display screen, the lower LED display screen required to be maintained may be easily taken down from the corresponding frame and taken out from the plurality of display assemblies. Therefore, the LED display screen required to be maintained is easy to repair. Furthermore, in the situation that a plurality of LED display screens are arranged above an LED display screen required to be maintained, the lower LED display screen to be maintained may be easily replaced and repaired, and front maintenance is convenient. Therefore, the technical solution of the disclosure may solve the problem that in the prior art, when a certain LED display screen at a lower layer is required to be repaired and replaced, all upper-layer LED display screens above the LED display screen are required to be detached, resulting in difficult repair.

### BRIEF DESCRIPTION OF THE DRAWINGS

The accompanying drawings of the description, which constitutes a part of the disclosure, are used to provide further understanding of the disclosure, and illustrative embodiments of the disclosure and the description thereof are used to explain the disclosure, which are not intended to unduly limit the disclosure. In the accompanying drawings:

FIG. 1 shows a solid schematic structural diagram of an embodiment of a light-emitting diode (LED) display device according to the disclosure;

FIG. 2 shows a solid schematic structural diagram in the situation that an upper LED display assembly of the LED display device in FIG. 1 is lifted by a gas bag;

FIG. 3 shows a solid schematic structural diagram in the situation that a lower LED display screen of the LED display device in FIG. 1 is taken out;

FIG. 4 shows a solid schematic structural diagram from another angle of the LED display device in FIG. 1;

FIG. 5 shows a schematic diagram of a gas source device of the LED display device in FIG. 1;

FIG. 6 shows a solid schematic structural diagram of a front side of a mounting box of the LED display device in FIG. 1;

FIG. 7 shows a solid schematic structural diagram of a back side of a mounting box of the LED display device in FIG. 1;

FIG. 8 shows an exploded schematic structural diagram of the LED display device in FIG. 1;

FIG. 9 shows an enlarged schematic diagram of a position A of the LED display device in FIG. 8;

FIG. 10 shows a solid schematic structural diagram in the situation that the LED display device in FIG. 4 is partially cut;

FIG. 11 shows an enlarged schematic diagram of a position B of the LED display device in FIG. 10;

FIG. 12 shows an enlarged schematic diagram of a position C of the LED display device in FIG. 10;

FIG. 13 shows an enlarged schematic diagram of a position D of the LED display device in FIG. 11;

FIG. 14 shows a solid schematic structural diagram of fasteners and damping members of the LED display device in FIG. 1;

FIG. 15 shows a solid schematic structural diagram of a gas bag of the LED display device in FIG. 1;

FIG. 16 shows a schematic front view of the LED display device in FIG. 1 with a plurality of LED display screens detached; and

FIG. 17 shows a solid schematic structural diagram of a frame of the LED display device in FIG. 1.

The above accompanying drawings include the following reference numerals:

10: support; 11: avoiding hole; 111: elongated hole section; 112: reamed hole section; 20: display assembly; 21: frame; 211: first accommodation recess; 212: second accommodation recess; 213: connecting hole; 22: LED display screen; 30: gas bag; 31: gas bag body; 32: gas nozzle; 40: gas source device; 41: gas pump; 42: inflator; 431: first gas channel; 432: second gas channel; 433: third gas channel; 434: fourth gas channel; 44: first gate valve; 45: overflow valve; 46: first one-way valve; 47: second one-way valve; 48: second gate valve; 51: longitudinal rod; 52: horizontal rod; 61: chute; 62: slide block; 63: ball; 64: limiting member; 71: fastener; 711: screw head; 712: screw rod; 72: damping member; 73: washer; 80: mounting box; 81: gas inlet; 82: gas outlet; 83: inflating port; and 84: gas pump switch.

### DETAILED DESCRIPTION OF THE EMBODIMENTS

The technical solutions of the embodiments of the disclosure will be clearly and completely described below in combination with the accompanying drawings in the embodiments of the disclosure. Apparently, the described embodiments are merely part rather than all of the embodiments of the disclosure. The following description of at least one illustrative embodiment is merely illustrative in nature and in no way serves as any limitation of the disclosure and application or uses thereof. On the basis of the embodiments of the disclosure, all other embodiments obtained by those of ordinary skill in the art without making inventive efforts all fall within the protection scope of the disclosure.

It should be noted that the terms used herein are merely for describing the specific implementations and are not intended to limit the illustrative implementations according to the disclosure. As used herein, a singular form is intended to include a plural form as well, unless the context clearly dictates otherwise, and in addition, it should be understood that the terms “contain” and/or “include”, when used in the description, specify the presence of features, steps, operations, devices, assemblies, and/or combinations thereof.

Unless specifically stated otherwise, relative arrangements, numerical expressions and values of the assemblies and steps stated in these embodiments do not limit the scope of the disclosure. Moreover, it should be understood that the sizes of the various parts shown in the accompanying drawings are not drawn according to an actual scale for ease of description. Technique, methods and devices known to those of ordinary skill in the related art may not be discussed in detail, but should be considered as a part of the authorized description where appropriate. In all examples shown and discussed herein, any specific value should be interpreted as merely illustrative and not as limiting. Thus, other examples of the illustrative embodiments can have different values. It should be noted that similar numerals and letters denote similar items in the following accompanying drawings, and therefore, once a certain item is defined in one figure, it is not required to be further discussed in the subsequent figures.

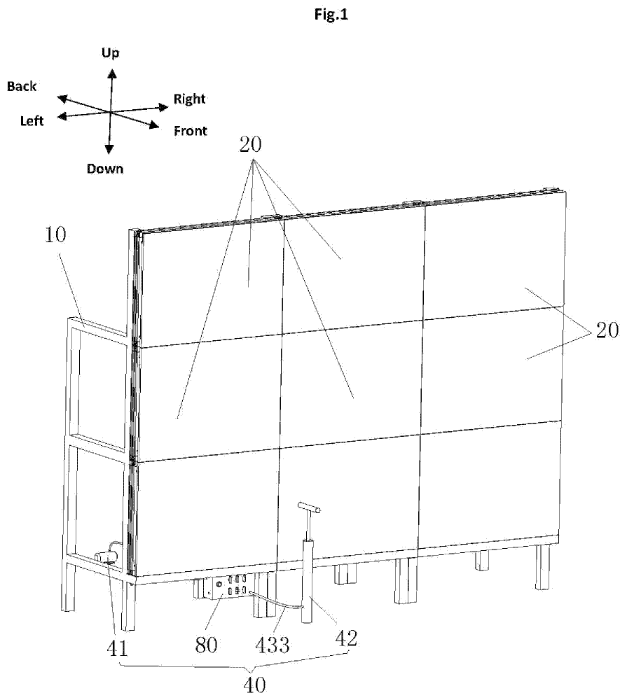

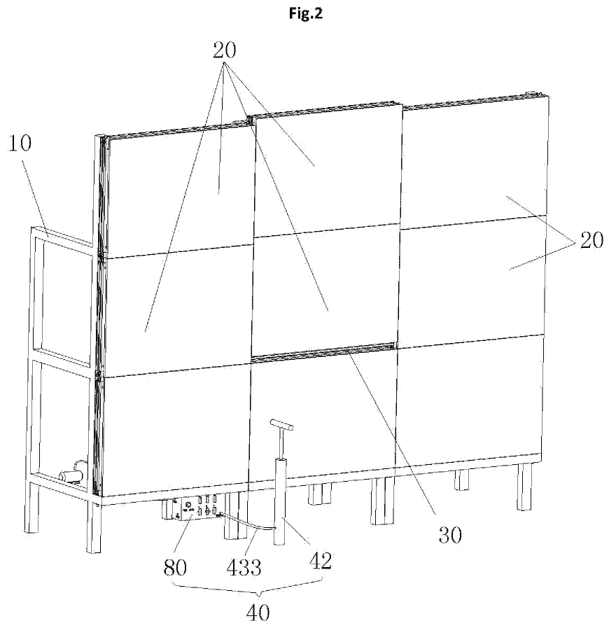

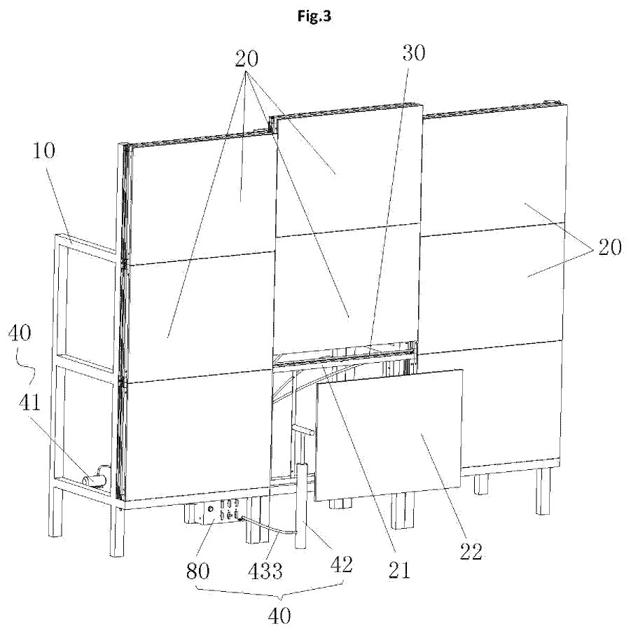

As shown in FIGS. 1-5, a light-emitting diode (LED) display device in the embodiment includes: a support 10, a plurality of display assemblies 20 and a plurality of gas bags 30. The plurality of display assemblies 20 are mounted on a front side of the support 10. The plurality of display assemblies 20 are arranged in an array on the support 10. Each display assembly 20 is slidably arranged in an upper-lower direction. Each display assembly 20 includes a frame 21 and an LED display screen 22 detachably arranged on a front side of the frame 21. Each gas bag 30 is arranged between the frames 21 of two display assemblies 20 adjacent to each other in the upper-lower direction, and each gas 30 bag has an expanded state and a flat state. In the embodiment, when the gas bag 30 is in the flat state, two adjacent display assemblies 20 located above and below the gas bag 30 cooperate with each other in a contact manner, and when the gas bag 30 is switched from the flat state to the expanded state, the frame 21 above the gas bag 30 may be driven to slide upwards, such that a detachment gap is formed between the two adjacent display assemblies 20 located above and below the gas bag 30.

By applying the technical solution of the embodiment, when the gas bag 30 is in the flat state, the two adjacent display assemblies 20 located above and below the gas bag 30 cooperate with each other in a contact manner. When a lower LED display screen 22 is required to be replaced, the gas bag 30 above the LED display screen 22 required to be repaired is switched from the flat state to the expanded state, and the frame 21 above the gas bag 30 may be driven to slide upwards, such that a detachment gap is formed between the two adjacent display assemblies 20 located above and below the gas bag 30. In this way, the LED display screen 22 above the lower LED display screen 22 required to be repaired is slightly lifted, such that the LED display screen 22 required to be maintained is not pressed by the upper LED display screen, the lower LED display screen 22 required to be maintained may be easily taken down from the corresponding frame 21 and taken out from the plurality of display assemblies 20. Therefore, the LED display screen 22 required to be maintained is easy to repair. Further, in the situation that a plurality of LED display screens 22 are arranged above an LED display screen 22 required to be maintained, the lower LED display screen 22 required to be maintained may be easily replaced and repaired, an enough repair space for operation of engineering personnel is not required to be reserved at a back portion of the LED display device, and front maintenance is convenient. Moreover, repair cost may be reduced, repair efficiency may be improved, and the purpose of independently repairing a broken LED display screen 22 may be realized. Therefore, the technical solution of the embodiment may solve the problem that in the prior art, when a certain LED display screen at a lower layer is required to be repaired and replaced, all upper-layer LED display screens above the LED display screen are required to be detached, resulting in difficult repair.

It should be noted that the above expanded state corresponds to a state of the gas bag 30 that is inflated, and the above flat state corresponds to a state of the gas bag 30 that is deflated or gasless.

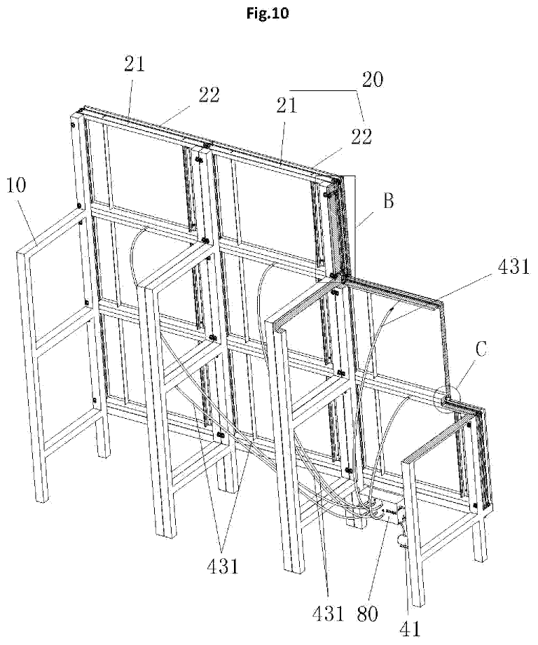

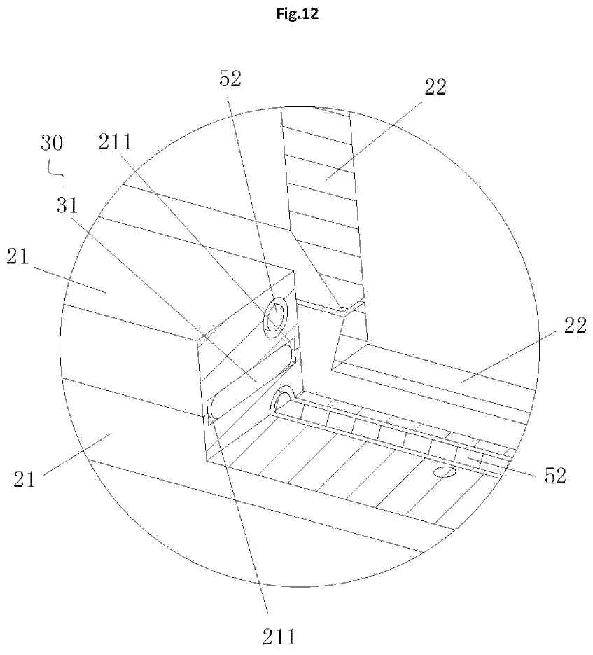

As shown in FIGS. 10, 12 and 15, each gas bag 30 includes a flat gas bag body 31 and a gas nozzle 32 arranged on the gas bag body 31. When the gas bag 30 is in the expanded state, the flat gas bag body 31 is attached to an upper surface and a lower surface of corresponding adjacent frames 21 located above and below, such that the gas bag 30 may stably lift the upper frame 21 and prevent the frame 21 from falling. Moreover, compared with a spherical or elliptical gas bag, the flat gas bag body 31 is narrower and longer, and occupies less space. When the gas bag 30 is in the flat state, in order to prevent the frames 21 of the two adjacent display assemblies 20 located above and below from pressing the gas bag 30 to damage the gas bag 30, first accommodation recesses 211 for accommodating the gas bag body 31 are provided on the frames 21 of the two adjacent display assemblies 20 located above and below, and the gas nozzle 32 passes through the frames 21.

As shown in FIGS. 1-5, the LED display device further includes a gas source device 40 for supplying gas to the plurality of gas bags 30. The gas source device 40 includes a gas pump 41 and an inflator 42, the gas source device 40 further includes a plurality of first gas channels 431 in communication with the gas pump 41 and the inflator 42, the plurality of first gas channels 431 are connected in parallel, the plurality of first gas channels 431 are in communication with the plurality of gas bags 30 in a one-to-one correspondence manner, and a first gate valve 44 is arranged on each of the first gas channels 431. The gas pump 41 inflates the plurality of gas bags 30 by the plurality of first gas channels 431, the plurality of gas bags and the plurality of first gas channels being arranged in a one-to-one correspondence manner. Each first gate valve 44 may connect or disconnect a corresponding first gas channel 431. For a lower LED display screen 22 required to be maintained, the gas bag 30 above the frame 21 corresponding to the LED display screen 22 is required to be inflated, and at this time, all the other first gate valves 44 may be closed, and only the first gate valve 44 of the gas bag 30 corresponding to the LED display screen 22 required to be maintained is opened. If there is no power source for supplying power to the gas pump 41 due to environmental restrictions, inflation may be manually carried out by the inflator 42 without affecting repair. The first gate valve 44 may be a manual valve or an electric valve. The first gate valve 44 is preferably a ball valve. The gas source device 40 in the embodiment uses air as a conductive medium, which is environment-friendly and pollution-free. The LED display device in the embodiment uses pneumatic transmission, which effectively reduces the number of mechanisms and parts for mechanical transmission, and may reduce cost.

Certainly, in embodiments not shown in the figures, the gas source device may only include a gas pump, and the gas source device further include a plurality of first gas channels in communication with the gas pump. The gas source device may only include an inflator, and the gas source device further include a plurality of first gas channels in communication with the inflator.

As shown in FIG. 5, the gas source device 40 further includes an overflow gas channel in communication with any one of the first gas channels 431, and an overflow valve 45 is arranged on the overflow gas channel. Through the arrangement of the overflow valve 45, a preset constant gas pressure is provided to the gas source device 40, so as to guarantee that the pressure is in a safe range, and guarantee safety of the gas pump, each first gas channel 431 and each gas bag 30.

As shown in FIG. 5, the gas source device 40 includes a gas pump 41 and an inflator 42. The gas pump 41 and the inflator 42 are connected in parallel, the plurality of first gas channels 431 converge at a junction, the junction is in communication with the gas pump 41 by a second gas channel 432, and a first one-way valve 46 is arranged on the second gas channel 432. Through the arrangement of the first one-way valve 46, gas in the second gas channel 432 is prevented from flowing back. A third gas channel 433 is arranged between an inlet of the first one-way valve 46 and the inflator 42, and a second one-way valve 47 is arranged on the third gas channel 433. Through the arrangement of the second one-way valve 47, gas in the third gas channel 433 is prevented from flowing back. A fourth gas channel 434 is arranged between the junction and an outlet of the first one-way valve 46, and a second gate valve 48 is arranged on the fourth gas channel 434. Through the arrangement of the second gate valve 48, gas in the second gas channel 432 and the first gas channel 431 may be conveniently discharged after the LED display device is front-maintained. The second gate valve 48 may be a manual valve or an electric valve. The second gate valve 48 is preferably a ball valve.

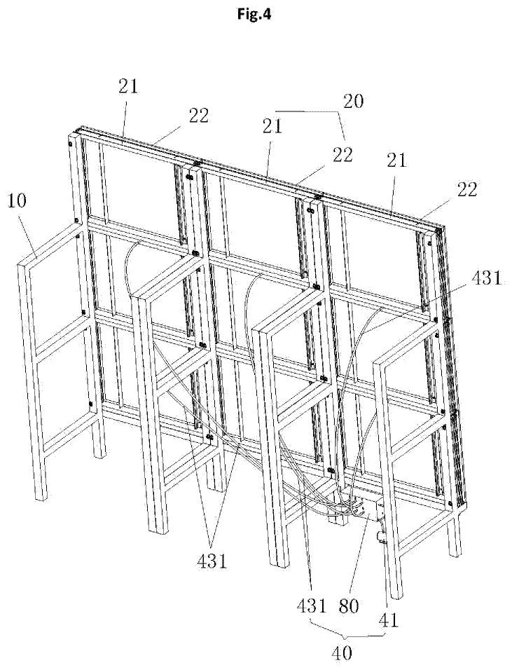

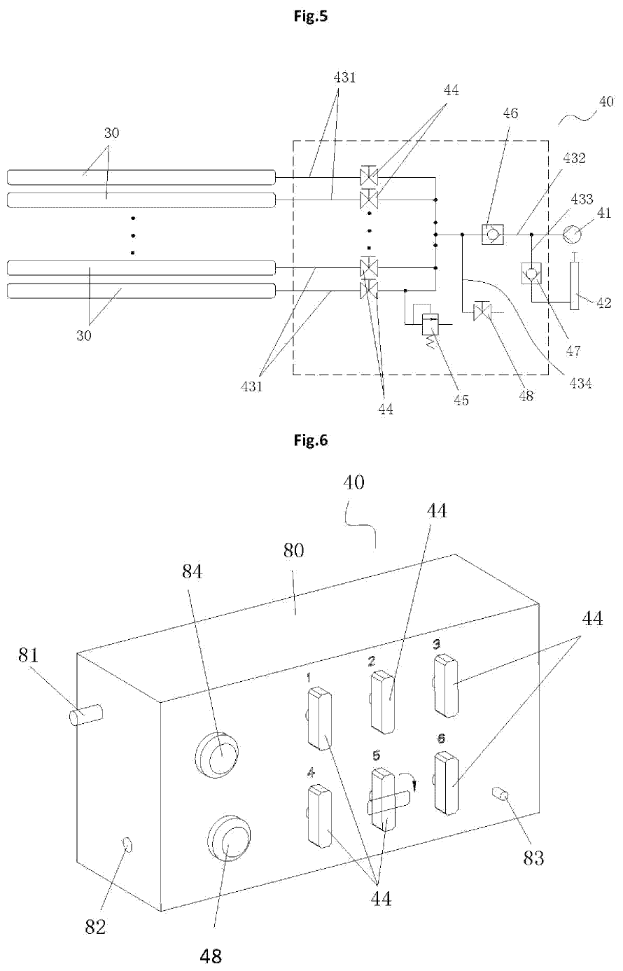

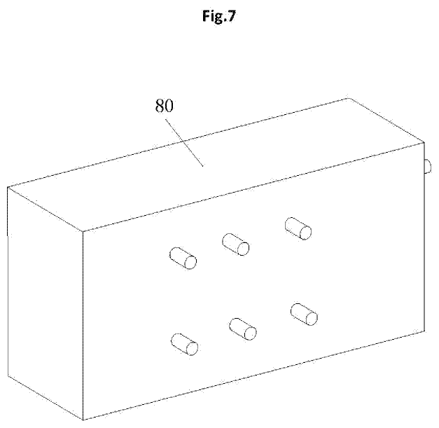

As shown in FIGS. 4-7, the gas source device 40 in the embodiment further includes a mounting box 80 located below the support 10, the above overflow gas channel, overflow valve 45, second gas channel 432, first one-way valve 46, fourth gas channel 434, and second one-way valve 47 are all mounted in the mounting box 80. A gas inlet 81, a gas outlet 82, an inflating port 83 and a gas pump switch 84 are provided on the mounting box 80 at intervals. The second gas channel 432 is in communication with the gas inlet 81, the fourth gas channel 434 is in communication with the gas outlet 82, and the third gas channel 433 is in communication with the inflating port 83. The gas pump 41 is located outside the mounting box 80, and the gas pump 41 is connected to the gas pump switch 84. Through the arrangement of the mounting box 80, the gas source device 40 is more compact in structure, and convenient to carry and operate. The second gate valve 48 and the plurality of first gate valves 44 are mounted on the mounting box 80 at intervals, the second gate valve 48 is normally in a closed state, and the plurality of first gate valves 44 are normally in a closed state.

It should be noted that three “▪” between two first gate valves 44 in FIG. 5 are ellipses, indicating that several first gate valves 44 are omitted. Three “▪” between two gas bags 30 in FIG. 5 are ellipses, indicating that several gas bags 30 are omitted.

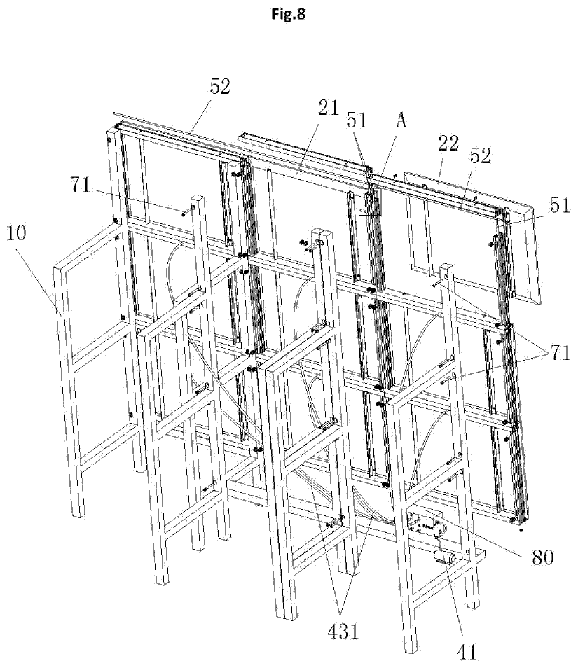

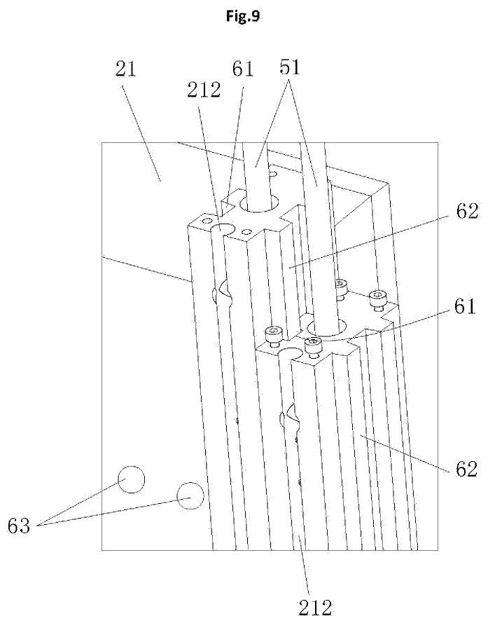

As shown in FIGS. 8-11, the LED display device further includes a plurality of longitudinal rods 51 arranged at intervals and a plurality of horizontal rods 52 arranged at intervals. The longitudinal rods 51 and the horizontal rods 52 are arranged in a staggered manner, there is a distance between the longitudinal rods 51 and the horizontal rods 52 in a front-back direction of support 10, every two adjacent longitudinal rods 51 pass through one frame 21, and every two adjacent horizontal rods 52 pass through one frame 21. In this way, a plurality of display assemblies 20 are assembled together by the plurality of longitudinal rods 51 and the plurality of horizontal rods 52 that are arranged in a staggered manner. A movement gap in the upper-lower direction is provided between through holes of each frame 21 allowing the horizontal rods 52 to pass through and the corresponding horizontal rods 52. Each longitudinal rod 51 pass through a plurality of display assemblies 20 arranged in a row in an up-down direction of support 10, and each horizontal rod 52 pass through a plurality of display assemblies 20 arranged in a row in a left-right direction of support 10. Each through hole of each frame 21 allowing the horizontal rod 52 to pass through may be a round hole or an elliptical hole having an aperture greater than an outer diameter of the horizontal rod 52, or may be an elongated hole having a minimum aperture greater than an outer diameter of the horizontal rod 52. The above movement gap has a diameter of 1 mm-3 mm.

As shown in FIGS. 8-11, first external threads are provided on portions of two ends of each longitudinal rod 51 protruding out of an upper surface and a lower surface of each of the plurality of LED display assemblies respectively, and the LED display device further includes first nuts connected to the first external threads. Second external threads are provided on portions of two ends of each horizontal rod 52 protruding out of a left surface and a right surface of each of the plurality of LED display assemblies respectively, and the LED display device further includes second nuts connected to the second external threads. When a lower LED display screen 22 is required to be repaired and replaced, the first nuts on the longitudinal rods 51 on two sides of a row where the LED display screen 22 required to be repaired is located is required to be unscrewed first, such that each frame 21 of the row where the LED display screen 22 required to be repaired is located may be loosened, and when the gas bag 30 above the LED display screen 22 required to be repaired is switched from the flat state to the expanded state, the frame 21 above the gas bag 30 may be driven to slide upwards.

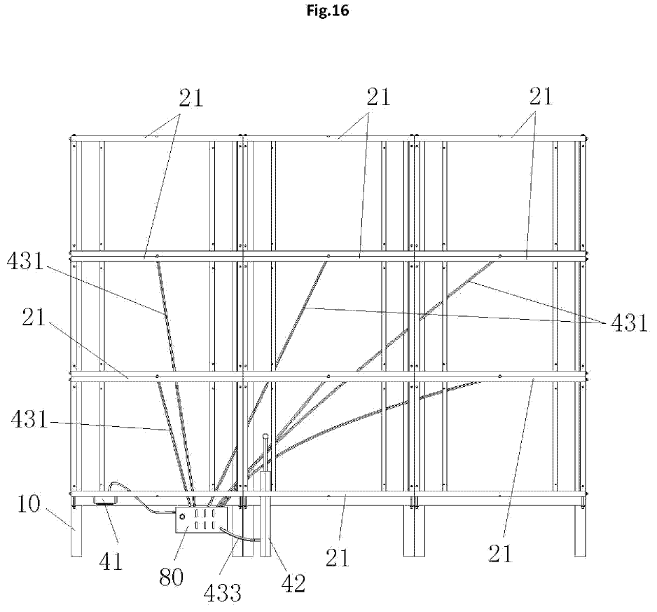

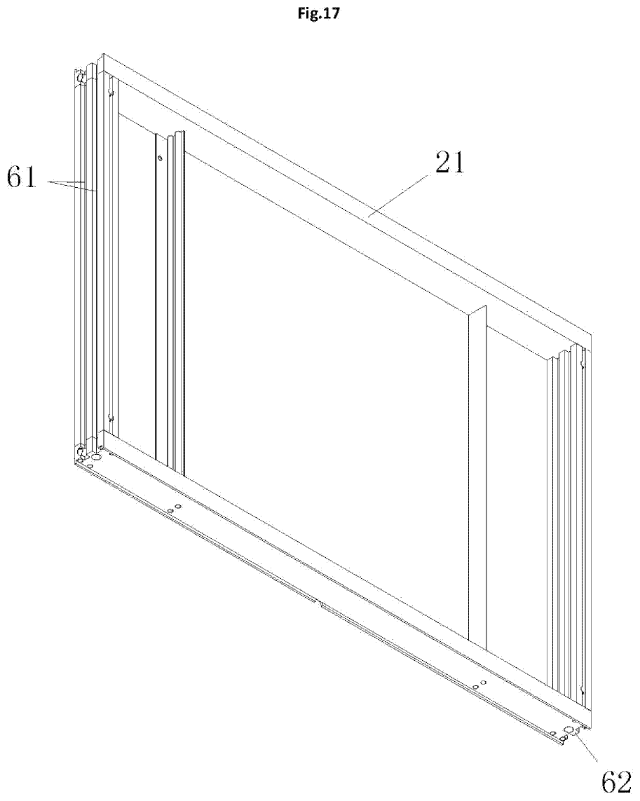

As shown in FIGS. 8, 9, 16 and 17, a chute 61 is provided on one frame 21 of two adjacent frames 21 located left and right, and a slide block 62 matching the chute 61 in an inserted manner is arranged on the other frame 21 of two adjacent frames 21. In this way, through matching between the chute 61 and the slide block 62, one frame 21 of two adjacent frames 21 located left and right may slide upwards relative to the other frame 21. Preferably, one chute 61 and one slide block 62 are arranged on a left side and a right side of one frame 21 for the convenience of processing and forming. In this way, the LED display device is simple in structure, and easy to mount and operate.

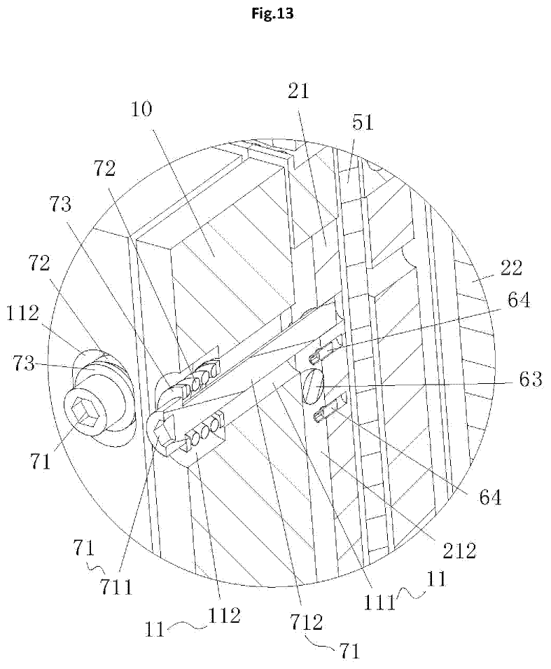

As shown in FIGS. 9 and 13, a second accommodation recess 212 for accommodating a ball 63 is provided on a back side of each frame 21, and a portion of each ball 63 protruding out of an opening of the second accommodation recess 212 matches a surface of the support 10 in a contact manner. Since contact between the ball 63 and the surface of the support 10 is point-to-surface contact, a friction coefficient is small. When a gas bag 30 above a LED display screen 22 required to be repaired is switched from the flat state to the expanded state, only a small support force is required to be provided by the gas bag 30 to lift the frame 21 above the gas bag 30, such that all the frames 21 above the gas bag 30 may slide upwards, which is easy and labor-saving. It should be noted that more than half of the ball 63 is located in the second accommodation recess 212, so as to prevent the ball 63 from being separated from the second accommodation recess 212 from a back side of the corresponding frame 21.

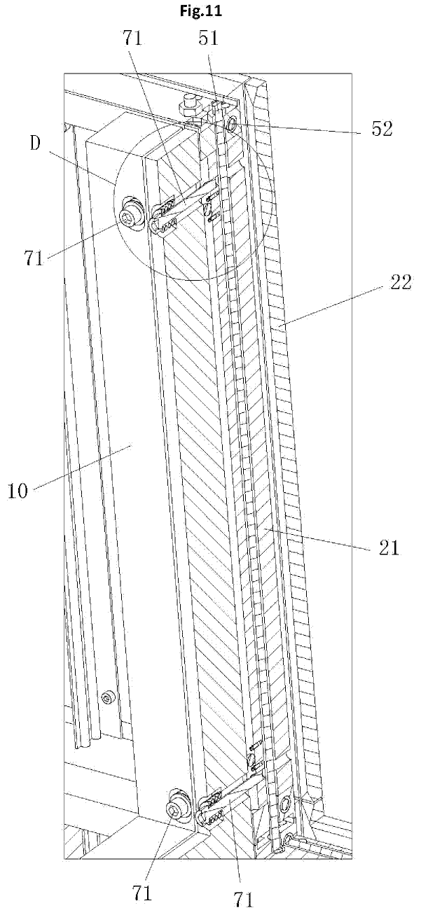

As shown in FIGS. 11 and 13, a pair of limiting members 64 located on an upper side and a lower side of the ball 63 is arranged on each frame 21, and the limiting members 64 are detachably located in the second accommodation recess 212. The pair of limiting members 64 limit the upper side and the lower side of the ball 63 respectively, and the ball 63 is only allowed to roll in the second accommodation recess 212, such that when the frame 21 slides upwards or downwards, the ball 63 is prevented from moving upwards or downwards, and a working position of the ball 63 in the second accommodation recess 212 is prevented from changing. Specifically, there are two balls 63 arranged in the second accommodation recess 212 at an interval in the upper-lower direction on each frame 21. In this way, the frame 21 may stably slide upwards conveniently. The limiting members 64 in the embodiment are preferably bolts, and heads of the bolts are located in the second accommodation recesses 212, so as to prevent the situation that the heads of the bolts are in contact with the surface of the support 10, so as to interfere with the surface of the support.

Specifically, as shown in FIGS. 9-12 and 17, each frame 21 includes a top beam and a bottom beam that may be oppositely spliced, and a first side beam and a second side beam that may be spliced between the top beam and the bottom beam, the top beam, the bottom beam, the first side beam and the second side beam defining a rectangular structure. The chutes 61 and the slide blocks 62 are arranged on the first side beams and the second side beams, and the chutes 61 on the first side beams are located outside the frames 21, and the slide blocks 62 on the second side beams are located outside the frames 21. Second accommodation recesses 212 are provided on the first side beams and the second side beams, and in order to conveniently mount the balls 63 in the second accommodation recesses 212, two ends of the second accommodation recess 212 on each first side beam extend to an upper surface and a lower surface of the first side beam respectively, and two ends of the second accommodation recess 212 on each second side beam extend to an upper surface and a lower surface of the second side beam respectively.

As shown in FIGS. 10-14, the LED display device further includes a plurality of fasteners 71 penetrating the support 10. One corresponding frame 21 is adjustably mounted on the support 10 by each fastener 71. In order to create a movement space for the fastener 71 in an upper-lower direction, avoiding holes 11 allowing the fasteners 71 to pass through are provided on the support 10, and each avoiding hole 11 has an aperture greater than an outer diameter of each fastener 71. Through the provision of the avoiding holes 11, the fasteners 71 may slide up and down with the frames 21 when the frames 21 slide up and down. Connecting holes 213 tightly connected to the fasteners 71 are provided on the frames 21, and the LED display device further includes a plurality of damping members 72, the damping members 72 and the fasteners 71 are arranged in a one-to-one correspondence manner, and the damping members 72 are located between the avoiding holes 11 and heads of the fasteners 71, such that the fasteners 71 may swing up and down in the avoiding holes 11 when the frames 21 slide up and down. Through the arrangement of the damping members 72, the heads of the fasteners 71 may be conveniently pressed on the support 10, such that the fasteners 71 are tightly connected in the connecting holes 213, and the frames 21 are adjustably fixed on the support 10.

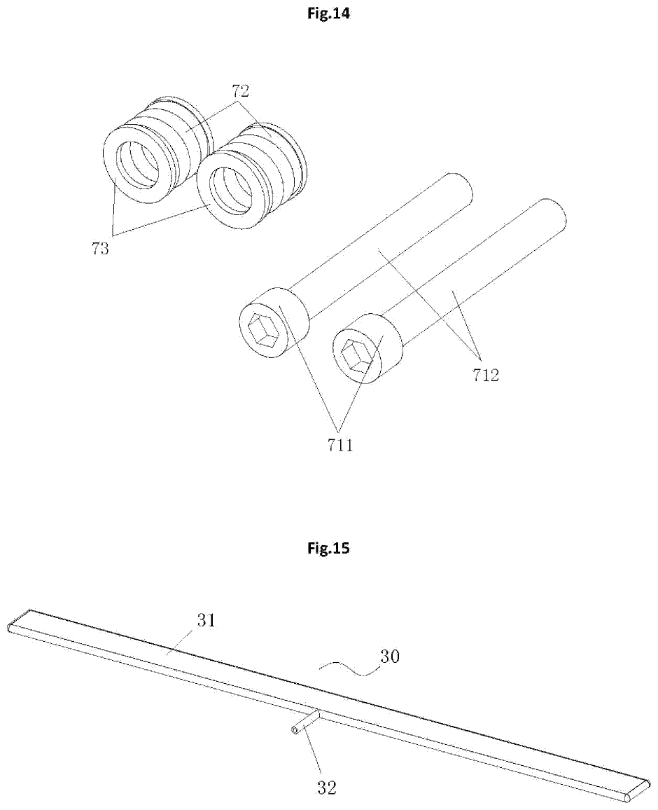

As shown in FIGS. 13 and 14, the fasteners 71 include screw heads 711 and screw rods 712 connected to the screw heads 711. The connecting holes 213 are screw holes connected to the screw rods 712, the avoiding holes 11 include elongated hole sections 111 for avoiding the screw rods 712 and reamed hole sections 112 for accommodating the screw heads 711, and each reamed hole section 112 has an aperture greater than a maximum value of apertures of the elongated hole sections 111. Through the arrangement of the elongated hole sections 111, the avoiding holes 11 may conveniently avoid the screw rods 712, such that the screw rods 712 may swing up and down in the avoiding holes 11 when the frames 21 slide up and down. Step surfaces are formed between the reamed hole sections 112 and the elongated hole sections 111, the damping members 72 include springs sleeving the screw rods 712, and the springs are located between the screw heads 711 and the step surfaces. The screw heads 711 and the step surfaces limit the springs, such that the springs may always apply elastic forces to the fasteners 71. With the elastic forces of the springs, the gaps between the balls 63 and the support 10 may be eliminated, such that the balls 63 are tightly pressed on the surface of the support 10 in a front-back direction of the support 10. In this way, in the situation that the frames 21 are fixed on the support 10 by the fasteners 71, when the gas bag 30 above the LED display screen 22 required to be repaired is switched from the flat state to the expanded state, the gas bag 30 may also lift the frame 21 above the gas bag 30, such that all the frames 21 above the gas bag 30 may slide upwards.

As shown in FIGS. 13 and 14, in the embodiment, the LED display device further includes washers 73 sleeving the fasteners 71, and the washers 73 are located between the screw heads 711 and the springs. In this way, through the arrangement of the washers 73, pressing forces applied to the springs by the fasteners 71 may be increased, such t-ZQShat adjustable fixation by the fasteners 71 is more reliable.

In the description of the disclosure, it should be understood that orientation or positional relations indicated by orientation words such as “front, back, upper, lower, left and right”, “horizontal, vertical, perpendicular to and parallel with”, and “top and bottom” are generally based on orientation or positional relations shown in the accompanying drawings, and are merely for the convenience of describing the disclosure and simplifying the description. Unless otherwise stated, these orientation words do not indicate or imply that devices or elements indicated thereby must have specific orientations or be constructed and operated in specific orientations, and therefore cannot be construed as limiting the protection scope of the disclosure. Orientation words “inside and outside” refer to an inside and an outside relative to an outline of each component.

For ease of description, spatial relative terms such as “on”, “above”, “on an upper surface” and “upper” can be used herein to describe spatial positional relations of one device or feature with other devices or features as shown in the figures. It should be understood that the spatial relative terms are intended to include different orientations in use or operation in addition to the orientations of the devices described in the figures. For example, if the device in the figures is inverted, the device described as “above” or “on” other devices or structures would then be positioned “below” or “under” the other devices or structures. Thus, the illustrative term “above” can include two orientations of “above” and “below.” The device can also be positioned in other different ways (being rotated by 90 degrees or being positioned at other orientations), and the spatial relative description used herein is interpreted accordingly.

In addition, it should be noted that the use of the terms “first”, “second”, etc. to define parts is merely for convenience of distinguishing corresponding parts. Unless otherwise stated, the above words do not have special meanings, and therefore cannot be understood as limiting the protection scope of the disclosure.

What is described above is merely preferred embodiments of the disclosure, and is not used to limit the disclosure, and for those skilled in the art, the disclosure can be variously modified and changed. Any modifications, equivalent replacements, improvements, etc. made within the spirit and principle of the disclosure should fall within the protection scope of the disclosure.

What is claimed is:

1. A light-emitting diode (LED) display device, comprising:
a support;
a plurality of display assemblies mounted on a front side of the support, wherein the plurality of display assemblies are arranged in an array on the support, each of the plurality of display assemblies is slidably arranged in an upper-lower direction, and each of the plurality of display assemblies comprises a frame and an LED display screen detachably arranged on a front side of the frame; and
a plurality of gas bags, wherein each of the plurality of gas bags is arranged between the frames of two display assemblies adjacent to each other in the upper-lower direction, each of the plurality of gas bags has an expanded state and a flat state,
when the gas bag is in the flat state, two adjacent display assemblies located above and below one of the plurality of gas bags cooperate with each other in a contact manner, and when the one of the plurality of gas bags is switched from the flat state to the expanded state, the frame above the one of the plurality of gas bags can be driven to slide upwards, such that a detachment gap is formed between the two adjacent display assemblies located above and below the one of the plurality of gas bags.

2. The LED display device as claimed in claim 1, wherein each of the plurality of gas bag comprises a flat gas bag body and a gas nozzle arranged on the gas bag body, first accommodation recesses for accommodating the gas bag body are provided on the frames of the two adjacent display assemblies located above and below, and the gas nozzle passes through the frames of the two adjacent display assemblies.

3. The LED display device as claimed in claim 1, further comprising a gas source device for supplying gas to the plurality of gas bags, the gas source device comprises a gas pump and/or an inflator, the gas source device further comprises a plurality of first gas channels in communication with the gas pump and/or the inflator, the plurality of first gas channels are connected in parallel, the plurality of first gas channels are in communication with the plurality of gas bags in a one-to-one correspondence manner, and a first gate valve is arranged on each of plurality of the first gas channels.

4. The LED display device as claimed in claim 3, wherein the gas source device further comprises an overflow gas channel in communication with any one of plurality of the first gas channels, and an overflow valve is arranged on the overflow gas channel.

5. The LED display device as claimed in claim 3, wherein the gas source device comprises the gas pump and the inflator, the gas pump and the inflator are connected in parallel, the plurality of first gas channels converge at a junction, the junction is in communication with the gas pump by a second gas channel, a first one-way valve is arranged on the second gas channel, a third gas channel is arranged between an inlet of the first one-way valve and the inflator, a second one-way valve is arranged on the third gas channel, a fourth gas channel is arranged between the junction and an outlet of the first one-way valve, and a second gate valve is arranged on the fourth gas channel.

6. The LED display device as claimed in claim 1, further comprising a plurality of longitudinal rods arranged at intervals and a plurality of horizontal rods arranged at intervals, each of plurality of the longitudinal rods and each of plurality of the horizontal rods are arranged in a staggered manner, every two adjacent longitudinal rods of plurality of the longitudinal rods pass through one frame, every two adjacent horizontal rods pass through one frame, and a movement gap in the upper-lower direction is provided between a through hole of each frame allowing the horizontal rods to pass through and a corresponding horizontal rod of plurality of horizontal rods.

7. The LED display device as claimed in claim 1, wherein a chute is provided on one frame of two adjacent frames located left and right, and a slide block matching the chute in an inserted manner is arranged on the other frame of two adjacent frames located left and right.

8. The LED display device as claimed in claim 1, wherein a second accommodation recess for accommodating a ball is provided on a back side of each frame, and a portion of the ball protruding out of an opening of the second accommodation recess cooperates with a surface of the support in a contact manner.

9. The LED display device as claimed in claim 8, wherein a pair of limiting members located on an upper side and a lower side of the ball is arranged on the frame, and the limiting members are detachably located in the second accommodation recess.

10. The LED display device as claimed in claim 1, further comprising a plurality of fasteners penetrating through the support, one corresponding frame is adjustably mounted on the support by each of the plurality of fasteners, an avoiding hole allowing the fasteners to pass through are provided on the support, an aperture of the avoiding hole is greater than an outer diameter of each of the plurality of fastener, connecting holes tightly connected to the plurality of fasteners are provided on the frames, the LED display device further comprises a plurality of damping members, the plurality of damping members and the plurality of fasteners are arranged in a one-to-one correspondence manner, and the damping members are located between the avoiding holes and heads of the fasteners, such that the fasteners can swing up and down in the avoiding holes when the frames slide up and down.

11. The LED display device as claimed in claim 10, wherein the fasteners comprise screw heads and screw rods connected with the screw heads, the connecting holes are screw holes connected with the screw rods, the avoiding holes comprise elongated hole sections for avoiding the screw rods, and reamed hole sections for accommodating the screw heads, an aperture of each of reamed hole sections is greater than a maximum value of an aperture of each of the elongated hole sections, step surfaces are formed between the reamed hole sections and the elongated hole sections, the damping members comprise springs sleeving the screw rods, and the springs are located between the screw heads and the step surfaces.
